(19) United States
(12) Patent Application Publication
(10) Pub. No.: US 2025/0169283 A1
(43) Pub. Date: May 22, 2025

(54) LIGHT-EMITTING DEVICE, DISPLAY DEVICE, PHOTOELECTRIC CONVERSION DEVICE, ELECTRIC EQUIPMENT, AND WEARABLE DEVICE

(71) Applicant: CANON KABUSHIKI KAISHA, Tokyo (JP)

(72) Inventors: HIROMASA TSUBOI, Tokyo (JP); MASATO YAJIMA, Tokyo (JP); TASUKU KANEDA, Kanagawa (JP)

(21) Appl. No.: 18/939,799

(22) Filed: Nov. 7, 2024

(30) Foreign Application Priority Data
Nov. 22, 2023 (JP) 2023-198524

(51) Int. Cl. H10K 59/121; H01L 21/762; H01L 27/12; H01L 29/786

(52) U.S. Cl. CPC H10K 59/1213; H01L 21/76224; H10D 30/6717; H10D 86/431; H10D 86/60

(57) ABSTRACT

A light-emitting device includes a plurality of pixels arranged in a substrate. Each pixel includes a light-emitting element, a driving transistor configured to supply a current to the light-emitting element, and a write transistor configured to supply a signal voltage to a gate of the driving transistor. The driving transistor has an offset structure that includes an insulator between the gate and a semiconductor region forming one of a source and a drain of the driving transistor in an orthogonal projection to a main surface of the substrate.

### BACKGROUND OF THE INVENTION

### Field of the Invention

The present invention relates to a light-emitting device, a display device, a photoelectric conversion device, electric equipment, and a wearable device.

### Description of the Related Art

Japanese Patent Laid-Open No. 2023-7804 describes a light-emitting device in which each pixel includes a light-emitting element, a driving transistor for supplying a current corresponding to a luminance signal to the light-emitting element, and a light emission control transistor for controlling light emission or non-light emission of the light-emitting element. The light emission control transistor is arranged between the light-emitting element and the driving transistor, and has a drain offset structure.

If an electric field in a semiconductor region forming a source or a drain of the driving transistor is large, for example, a leakage current flowing between the source and the drain is accelerated and increased by the electric field, so that a current flowing into the light-emitting element can increase. This unintentionally sets the light-emitting element in a light emission state.

### SUMMARY OF THE INVENTION

One aspect of the present invention provides a technique advantageous in suppressing that a leakage current flowing into a light-emitting element from a driving transistor unintentionally sets the light-emitting element in a light emission state.

One of aspects of the present invention provides a light-emitting device including a plurality of pixels arranged in a substrate, wherein each pixel includes a light-emitting element, a driving transistor configured to supply a current to the light-emitting element, and a write transistor configured to supply a signal voltage to a gate of the driving transistor, and the driving transistor has an offset structure that includes an insulator between the gate and a semiconductor region forming one of a source and a drain of the driving transistor in an orthogonal projection to a main surface of the substrate.

Further features of the present invention will become apparent from the following description of exemplary embodiments with reference to the attached drawings.

### BRIEF DESCRIPTION OF THE DRAWINGS

FIG. 1 is a view showing the arrangement of a light-emitting device according to the first embodiment;

FIG. 2 is a view showing the arrangement of a pixel of the light-emitting device according to the first embodiment;

FIG. 3 is a plan view showing the arrangement of the pixel of the light-emitting device according to the first embodiment;

FIG. 4 is a sectional view showing the arrangement of the pixel of the light-emitting device according to the first embodiment;

FIG. 5 is a view showing the arrangement of a light-emitting device according to the second embodiment;

FIG. 6 is a view showing the arrangement of a pixel of the light-emitting device according to the second embodiment;

FIG. 7 is a plan view showing the arrangement of the pixel of the light-emitting device according to the second embodiment;

FIG. 8 is a sectional view showing the arrangement of the pixel of the light-emitting device according to the second embodiment;

FIG. 9 is a view showing the arrangement of a light-emitting device according to the third embodiment;

FIG. 10 is a view showing the arrangement of a pixel of the light-emitting device according to the third embodiment;

FIG. 11 is a plan view showing the arrangement of the pixel of the light-emitting device according to the third embodiment;

FIG. 12 is a sectional view showing the arrangement of the pixel of the light-emitting device according to the third embodiment;

FIG. 13 is a schematic view showing an example of a display device according to an embodiment;

FIGS. 14A and 14B are views each showing an example of an image capturing device according to an embodiment;

FIGS. 15A and 15B are views each showing an example of a display device according to an embodiment; and

FIGS. 16A and 16B are views each showing an example of a wearable device according to an embodiment.

### DESCRIPTION OF THE EMBODIMENTS

Hereinafter, embodiments will be described in detail with reference to the attached drawings. Note, the following embodiments are not intended to limit the scope of the claimed invention. Multiple features are described in the embodiments, but limitation is not made to an invention that requires all such features, and multiple such features may be combined as appropriate. Furthermore, in the attached drawings, the same reference numerals are given to the same or similar configurations, and redundant description thereof is omitted.

In this specification, terms “first conductivity type” and “second conductivity type” can be used to distinguish between “p type” and “n type”. When the first conductivity type is the p type, the second conductivity type is the n type. On the other hand, when the first conductivity type is the n type, the second conductivity type is the p type.

A light-emitting device according to an embodiment includes a plurality of pixels arranged in a substrate, and each pixel can include a light-emitting element, a driving transistor that supplies a current to the light-emitting element, and a write transistor that supplies a signal voltage to the gate electrode of the driving transistor. The driving transistor and the write transistor may be p-type transistors or n-type transistors. To provide a more specific example, for a sake of convenience, an example will be described below in which the driving transistor and the write transistor are formed by p-type transistors. However, the driving transistor may be formed by a p-type transistor and the write transistor may be formed by an n-type transistor. Alternatively, the driving transistor may be formed by an n-type transistor and the write transistor may be formed by a p-type transistor. Each pixel in the light-emitting device may further include other transistors such as a reset transistor. The reset transistor may be a p-type or n-type transistor. The circuit arrangement of the pixel can be changed, as appropriate, in accordance with the conductivity types of the transistors forming the circuit. The light-emitting element can be an organic light-emitting element, but may be, for example, a light-emitting element including a light-emitting layer made of an inorganic material.

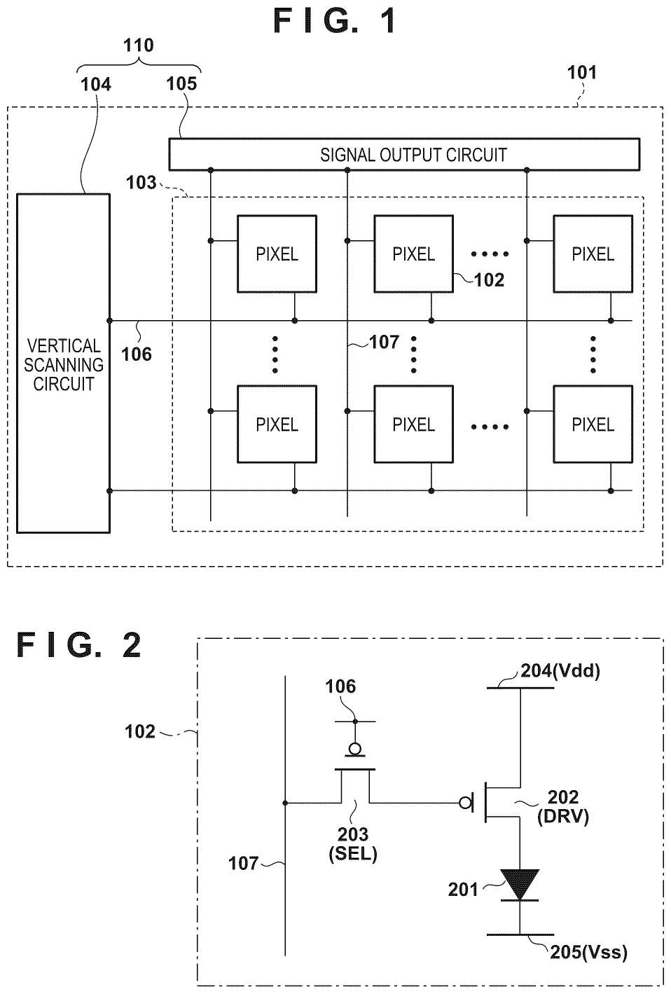

With reference to FIGS. 1 to 4, a light-emitting device 101 according to the first embodiment will be described below. FIG. 1 shows the arrangement of the light-emitting device 101 according to the first embodiment. The light-emitting device 101 can be formed as, for example, an organic light-emitting device. The light-emitting device 101 can include a pixel array 103. The pixel array 103 can include a plurality of pixels 102. The plurality of pixels 102 can be arranged in a substrate. The plurality of pixels 102 can be arranged to form, for example, a plurality of rows and a plurality of columns. Each light-emitting element 201 can include an anode, an organic layer including a light-emitting layer, and a cathode. The organic layer can include, in addition to the light-emitting layer, a hole injection layer, a hole transport layer, an electron injection layer, and an electron transport layer. The pixel array 103 can include a plurality of scanning lines 106 extending along rows and a plurality of signal lines 107 extending along columns.

The light-emitting device 101 can include a driving circuit 110 that drives the pixel array 103. The driving circuit 110 can include a vertical scanning circuit 104 that drives the plurality of scanning lines 106 to control writing of a signal voltage (luminance signal) in the pixels 102 in each row, and a signal output circuit 105 that drives the plurality of signal lines 107 to supply the luminance signal to the pixels 102 in each column.

FIG. 2 exemplarily shows an equivalent circuit showing the arrangement of one pixel 102. The pixel 102 can include the light-emitting element 201, a driving transistor 202 that drives the light-emitting element 201, and a write transistor 203 that supplies a signal voltage to the gate electrode of the driving transistor 202. The first electrode (the anode in this example) of two electrodes of the light-emitting element 201 can be connected to one (the drain in this example) of the source and drain of the driving transistor 202. The other (the source in this example) of the source and drain of the driving transistor 202 can be connected to a first power supply terminal 204 (to be referred to as a Vdd hereinafter). The second electrode (the cathode in this example) of the light-emitting element 201 can be connected to a second power supply terminal 205 (to be referred to as a Vss hereinafter). One of the source and drain of the write transistor 203 is connected to the gate of the driving transistor 202, and the other of the source and drain of the write transistor 203 is connected to the signal line 107. The gate of the write transistor 203 is connected to the scanning line 106.

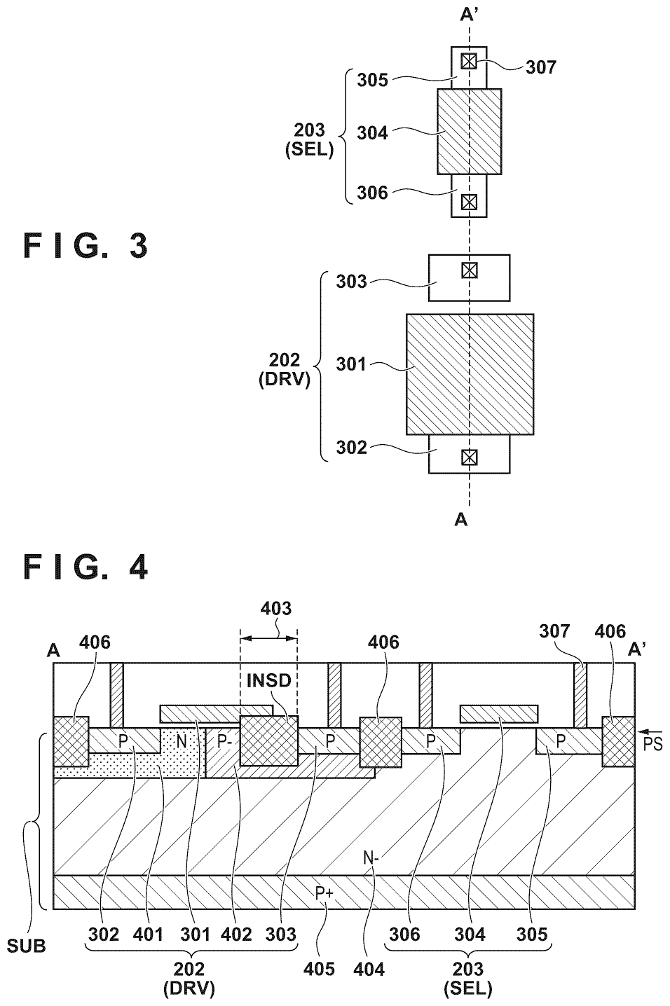

FIGS. 3 and 4 are a plan view and a sectional view, respectively, schematically showing the arrangement of the driving transistor 202 and the write transistor 203 of the pixel 102 shown in FIG. 2. FIG. 4 shows a section taken along a line A-A′ in FIG. 3. The pixel 102 is arranged in a substrate SUB. Of two broadest surfaces of the substrate SUB, the surface where the driving transistor 202 is arranged (the surface in contact with the gate insulating film of the driving transistor 202) is referred to as a main surface PS.

The driving transistor 202 is a MOS transistor including a gate 301, a source 302, and a drain 303. The gate 301 can be arranged on the main surface PS via the gate insulating film. The driving transistor 202 can have an offset structure that includes an insulator INSD between the gate 301 and a semiconductor region forming the source 302 or the drain 303 in an orthogonal projection (planar view) to the main surface PS of the substrate SUB. In the example shown in FIGS. 3 and 4, the driving transistor 202 has an offset structure that includes the insulator INSD between the gate 301 and a semiconductor region forming the drain 303 in an orthogonal projection to the main surface PS of the substrate SUB. Such an offset structure can also be called a drain offset structure. The insulator INSD can be, for example, a Shallow Trench Isolation (STI) or a Local Oxidation Of Silicon (LOCOS). The write transistor 203 is a MOS transistor including a gate 304, a source 305, and a drain 306. A via plug 307 can be connected to each of the sources 302 and 305 and the drains 303 and 306. The light-emitting element 201 can be arranged above the via plugs 307, but the light-emitting element 201 is not shown in FIG. 4.

In an example, the source 302 of the driving transistor 202 can be formed by the first semiconductor region of the first conductivity type (the p type in this example), and the drain 303 of the driving transistor 202 can be formed by the second semiconductor region of the first conductivity type. In a current path from the first semiconductor region of the first conductivity type forming the source 302 to the second semiconductor region of the first conductivity type forming the drain 303, a third semiconductor region 401 of the second conductivity type (the n type in this example) and a fourth semiconductor region 402 of the first conductivity type can be arranged in this order. The net impurity concentration of the first conductivity type in the fourth semiconductor region 402 is lower than the net impurity concentration of the first conductivity type in the second semiconductor region forming the drain 303.

The fourth semiconductor region 402 of the first conductivity type is arranged to bypass the insulator INSD, and the insulator INSD functions as an offset portion 403 that offsets the drain 303. In an example, the depth of the bottom surface of the insulator INSD using the main surface PS as a reference (the distance from the main surface PS to the bottom surface of the insulator INSD) is greater than the depth of the bottom surface of the drain 303 (the semiconductor region forming the drain 303) using the main surface PS as a reference.

The source 305 of the write transistor 203 can be formed by a semiconductor region of the first conductivity type, and the drain 306 of the write transistor 203 can be formed by a semiconductor region of the first conductivity type. The substrate SUB can include, for example, a semiconductor layer 405 of the first conductivity type, and a semiconductor layer 404 (well) of the second conductivity type arranged on the semiconductor layer 405. Each of the sources 302 and 305, the drains 303 and 306, and the semiconductor regions 401 and 402 of the driving transistor 202 and the write transistor 203 can be formed by implanting an impurity into the semiconductor layer 404. The substrate SUB includes isolation portions 406 for isolating transistors such as the driving transistor 202 and the write transistor 203 from each other. The isolation portion 406 can be, for example, an STI isolation, a LOCOS isolation, or a diffusion layer isolation of the second conductivity type.

According to the first embodiment, the electric field in the vicinity of the gate end of the driving transistor 202 on the drain side (the right end of the gate 301 in FIG. 4) can be reduced. Accordingly, it is possible to suppress that a leakage current flowing between the source and the drain or between the well and the drain is accelerated and increased by the electric field in the vicinity of the gate end. This is useful for suppressing that the leakage current flowing into the light-emitting element 201 from the driving transistor 202 unintentionally sets the light-emitting element 201 in the light emission state. For example, when the light-emitting device 101 is formed as a display device, this effect enables high-quality black display.

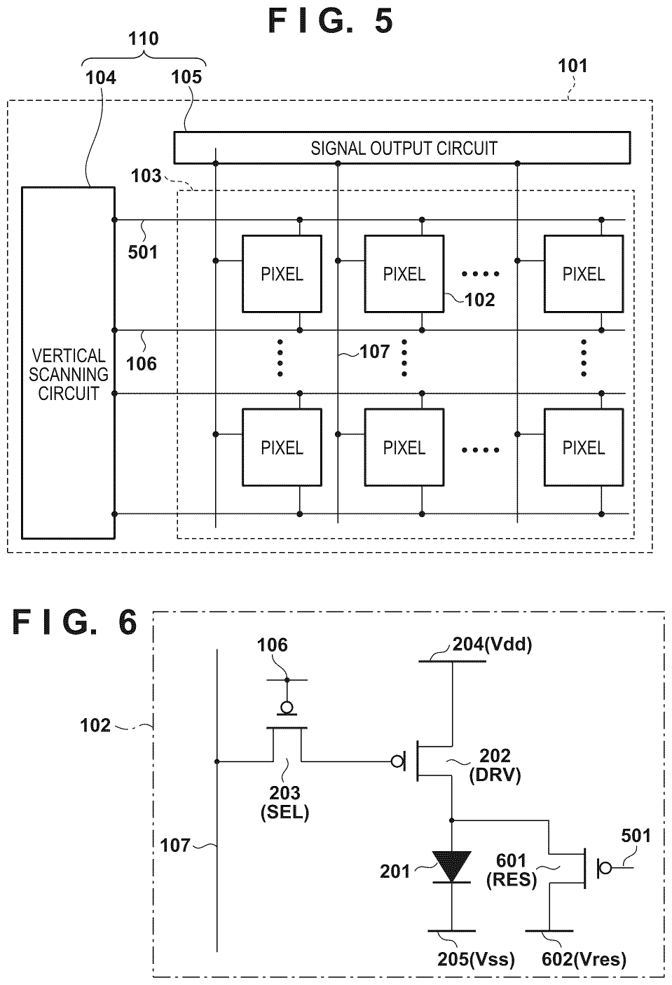

With reference to FIGS. 5 to 8, a light-emitting device 101 according to the second embodiment will be described. Matters not mentioned as the second embodiment can follow the first embodiment. In the light-emitting device 101 according to the second embodiment, each pixel 102 includes a reset transistor 601 to reset a light-emitting element 201. FIG. 5 shows the arrangement of the light-emitting device 101 according to the second embodiment. In the second embodiment, a pixel array 103 can include a plurality of first scanning lines 106 extending along rows, a plurality of second scanning lines 501 extending along rows, and a plurality of signal lines 107 extending along columns. In addition to driving the plurality of first scanning lines 106 to control writing of a signal voltage (luminance signal) in the pixels 102 in each row, a vertical scanning circuit 104 drives the plurality of second scanning lines 501 to reset the light-emitting elements 201 of the pixels 102 in each column.

FIG. 6 exemplarily shows an equivalent circuit showing the arrangement of one pixel 102 in the second embodiment. The pixel 102 can include, in addition to the light-emitting element 201, a driving transistor 202, and a write transistor 203, the reset transistor 601 that resets the light-emitting element 201. One (the source in this example) of the source and drain of the reset transistor 601 can be connected to one (the drain in this example) of the source and drain of the driving transistor 202. The other of the source and drain of the reset transistor 601 can be connected to a third power supply terminal 602 (to be referred to as a Vres hereinafter). The gate of the reset transistor 601 is connected to the second scanning line 501. When the second scanning line 501 is activated, the reset transistor 601 is set in the ON state, and the anode of the light-emitting element 201 is accordingly connected to the Vres 602, thereby resetting the luminance of the light-emitting element 201 to the black level. This is advantageous in implementing, for example, the light-emitting device 101 with high contrast. On the other hand, when causing the light-emitting element 201 to emit light in accordance with the luminance signal, the second scanning line 501 is inactivated to set the reset transistor 601 in the OFF state. At this time, the gate of the reset transistor 601 is at a high level potential (for example, the Vdd). On the other hand, the potential of the anode of the light-emitting element 201 can have a potential lower than the Vdd, so that an electric field is generated between the anode of the light-emitting element 201 and the gate of the reset transistor 601. If this electric field is large, the leakage current between the well and the source of the reset transistor 601 can be accelerated and increased. The second embodiment can reduce this electric field.

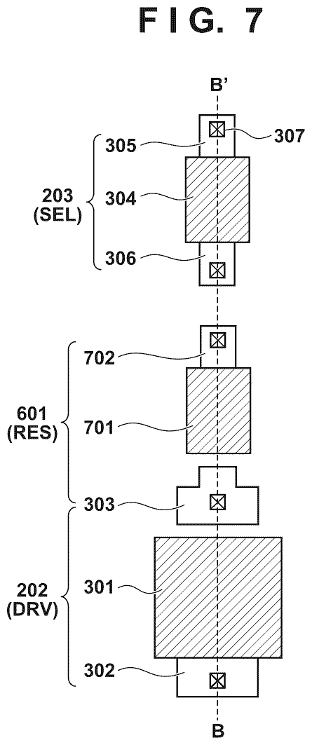

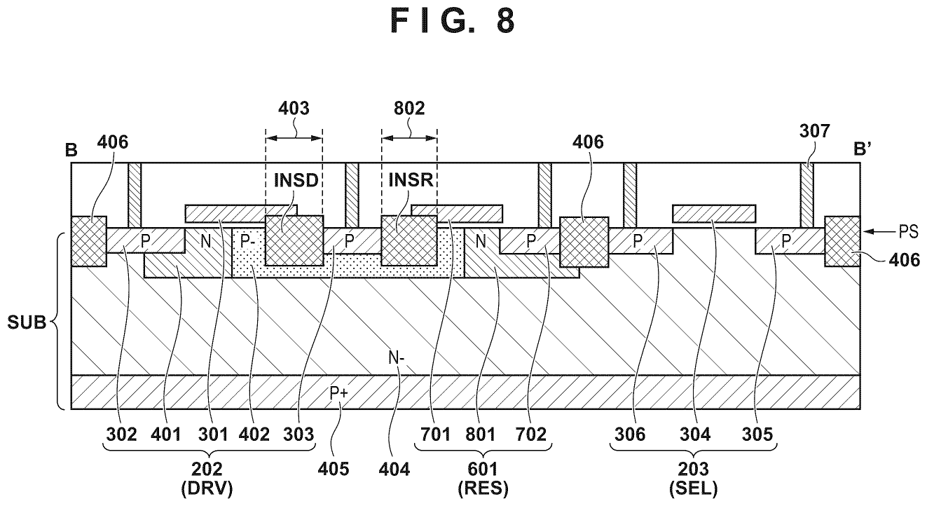

FIGS. 7 and 8 are a plan view and a sectional view, respectively, schematically showing the arrangement of the driving transistor 202, the write transistor 203, and the reset transistor 601 of the pixel 102 shown in FIG. 6. FIG. 8 shows a section taken along a line B-B′ in FIG. 7. The reset transistor 601 is a MOS transistor including a gate 701, a source 303, and a drain 702. In this example, the source 303 of the reset transistor 601 is in common with the drain 303 of the driving transistor 202, but the source of the reset transistor 601 may be provided separately from the drain of the driving transistor 202. The reset transistor 601 can have an offset structure that includes an insulator INSR between the source 303 of the reset transistor 601 and the gate 701 of the reset transistor 601 in an orthogonal projection to a main surface PS of a substrate SUB. Such an offset structure can also be called a source offset structure. The insulator INSR can be, for example, an STI or a LOCOS.

In an example, a source 302 of the driving transistor 202 can be formed by the first semiconductor region of the first conductivity type, and the drain 303 of the driving transistor 202 (the source 303 of the reset transistor 601) can be formed by the second semiconductor region of the first conductivity type. In a current path from the first semiconductor region forming the source 302 of the driving transistor 202 to the second semiconductor region forming the drain 303 of the driving transistor 202, a third semiconductor region 401 of the second conductivity type and a fourth semiconductor region 402 of the first conductivity type can be arranged in this order. The net impurity concentration of the first conductivity type in the fourth semiconductor region 402 is lower than the net impurity concentration of the first conductivity type in the second semiconductor region forming the drain 303 of the driving transistor 202. The fourth semiconductor region 402 of the first conductivity type is arranged to bypass an insulator INSD, and the insulator INSD functions as an offset portion 403 that offsets the drain 303 of the driving transistor 202. In an example, the depth of the bottom surface of the insulator INSD using the main surface PS as a reference (the distance from the main surface PS to the bottom surface of the insulator INSD) is greater than the depth of the bottom surface of the drain 303 (the semiconductor region forming the drain 303) using the main surface PS as a reference.

In an example, the drain 702 of the reset transistor 601 can be formed by the fifth semiconductor region of the first conductivity type. In a current path from the second semiconductor region forming the source 303 of the reset transistor 601 to the fifth semiconductor region forming the drain 702 of the reset transistor 601, the fourth semiconductor region 402 of the first conductivity type and a sixth semiconductor region 801 of the second conductivity type can be arranged in this order. The net impurity concentration of the first conductivity type in the fourth semiconductor region 402 is lower than the net impurity concentration of the first conductivity type in the second semiconductor region forming the drain 303 of the driving transistor 202 (the source 303 of the reset transistor 601). The fourth semiconductor region 402 of the first conductivity type is arranged to bypass the insulator INSR, and the insulator INSR functions as an offset portion 802 that offsets the source 303 of the reset transistor 601. In an example, the depth of the bottom surface of the insulator INSR using the main surface PS as a reference (the distance from the main surface PS to the bottom surface of the insulator INSR) is greater than the depth of the bottom surface of the source 303 (the semiconductor region forming the source 303) using the main surface PS as a reference.

According to the second embodiment, the electric field in the vicinity of the gate end of the reset transistor 601 on the source side (the left end of the gate 701 in FIG. 8) can be reduced, and a leakage current flowing between the well and the source can be suppressed. This is useful for suppressing that the leakage current flowing into the light-emitting element 201 from the reset transistor 601 unintentionally sets the light-emitting element 201 in the light emission state. For example, when the light-emitting device 101 is formed as a display device, this effect enables high-quality black display.

The leakage currents flowing into the light-emitting element 201 from the driving transistor 202 and the reset transistor 601 can depend on the lengths of the offset portion 403 and the offset portion 802, respectively. Hence, the length of the offset portion 403 and the length of the offset portion 802 may be individually adjusted. In another viewpoint, the length of the offset portion 403 may be different from the length of the offset portion 802. Here, the length of the offset portion 403 is the length of the insulator INSD of the driving transistor 202 in the channel length direction of the driving transistor 202. The length of the offset portion 802 is the length of the insulator INSR of the reset transistor 601 in the channel length direction of the reset transistor 601.

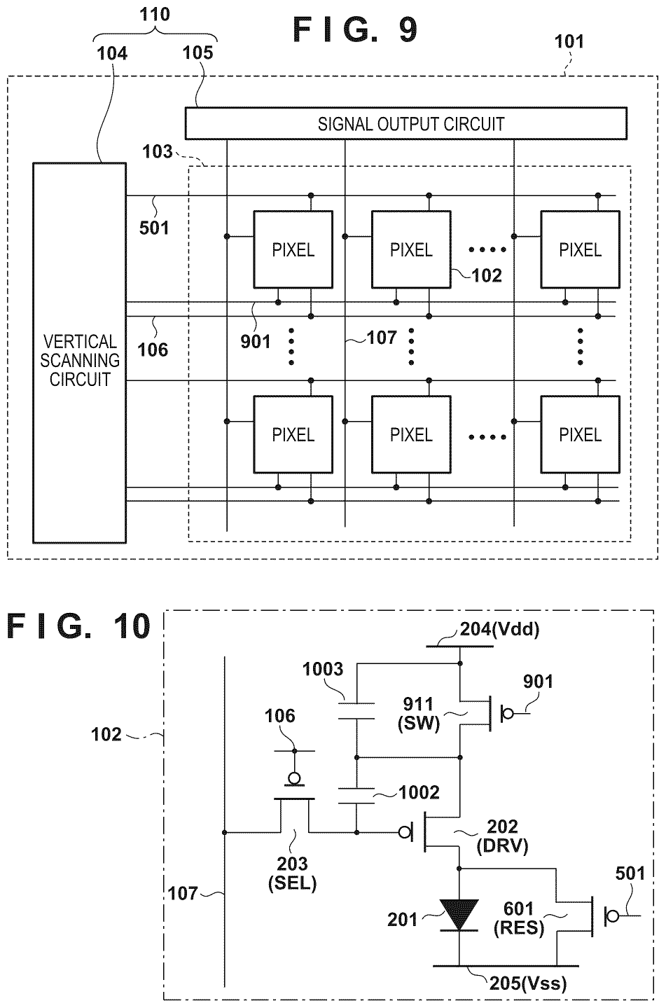

With reference to FIGS. 9 to 12, a light-emitting device 101 according to the third embodiment will be described. Matters not mentioned as the third embodiment can follow the first and second embodiments. In the light-emitting device 101 according to the third embodiment, each pixel 102 includes a light emission control transistor 911 that controls current supply from a Vdd 204 to a driving transistor 202. FIG. 9 shows the arrangement of the light-emitting device 101 according to the third embodiment. In the third embodiment, a pixel array 103 can include a plurality of first scanning lines 106 extending along rows, a plurality of second scanning lines 501 extending along rows, a plurality of third scanning lines 901 extending along rows, and a plurality of signal lines 107 extending along columns. A vertical scanning circuit 104 drives the plurality of first scanning lines 106 to control writing of a signal voltage (luminance signal) in the pixels 102 in each row, and drives the plurality of second scanning lines 501 to reset light-emitting elements 201 of the pixels 102 in each row. The vertical scanning circuit 104 drives the plurality of third scanning lines 901 to control the period during which the light-emitting elements 201 of the pixels 102 in each row are caused to emit light (in another viewpoint, light emission and non-light emission).

FIG. 10 exemplarily shows an equivalent circuit showing the arrangement of one pixel 102 in the third embodiment. The pixel 102 can include the light-emitting element 201, the driving transistor 202, a write transistor 203, and a reset transistor 601 as in the second embodiment. The pixel 102 can further include the light emission control transistor 911 that controls the period during which the light-emitting element 201 is caused to emit light. One (the drain in this example) of the source and drain of the light emission control transistor 911 can be connected to one (the source in this example) of the source and drain of the driving transistor 202. The other (the source in this example) of the source and drain of the light emission control transistor 911 can be connected to the Vdd 204. The gate of the light emission control transistor 911 is connected to the third scanning line 901.

The pixel 102 can include a first capacitive element 1002 connected between the gate of the driving transistor 202 and the source of the driving transistor 202, and a second capacitive element 1003 connected between the source of the driving transistor 202 and the Vdd 204. Each of the first capacitive element 1002 and the second capacitive element 1003 may be, for example, a parasitic capacitance, or may have a Metal-Insulator-Metal (MIM) structure.

The light emission control transistor 911 is a MOS transistor including a gate, a source, and a drain. When the light emission control transistor 911 is set in the ON state in response to a light emission control signal applied from the vertical scanning circuit 104 to the gate via the third scanning line 901, a current can be supplied from the Vdd 204 to the driving transistor 202. With this, the light-emitting element 201 is driven by the driving transistor 202, and the light-emitting element 201 emits light. That is, the light emission control transistor 911 functions to control the period during which the light-emitting element 201 is caused to emit light. In another viewpoint, the light emission control transistor 911 functions to control the light emission/non-light emission of the light-emitting element 201. In still another viewpoint, the light emission control transistor 911 has a function of controlling the ratio of the light emission period and the non-light emission period of the light-emitting element 201, that is, the duty ratio. The duty ratio control can reduce afterimage blurring accompanying light emission from each pixel 102 over a period of one frame. This can improve the image quality of a moving image in particular.

Due to manufacturing variations, the threshold of the driving transistor 202 may be different for each pixel. In this case, if the same signal voltage is written in multiple pixels which emit light of the same color, the amount of current flowing through the driving transistor 202 changes for each pixel, and the light emission amount can vary. To solve this problem, before writing the signal voltage, a so-called threshold correction operation of holding a threshold between the gate and source of the driving transistor 202 is preferably performed. This threshold correction operation can reduce the variation in current amount of the driving transistor 202 among the pixels, thereby implementing more uniform light emission. In the threshold correction operation, after causing a current to flow through the light-emitting element 201 via the light emission control transistor 911 and the driving transistor 202, the light emission control transistor 911 is set in the OFF state. With this, the current flows through the light-emitting element 201 until the gate-source voltage of the driving transistor 202 is settled, thereby performing threshold correction.

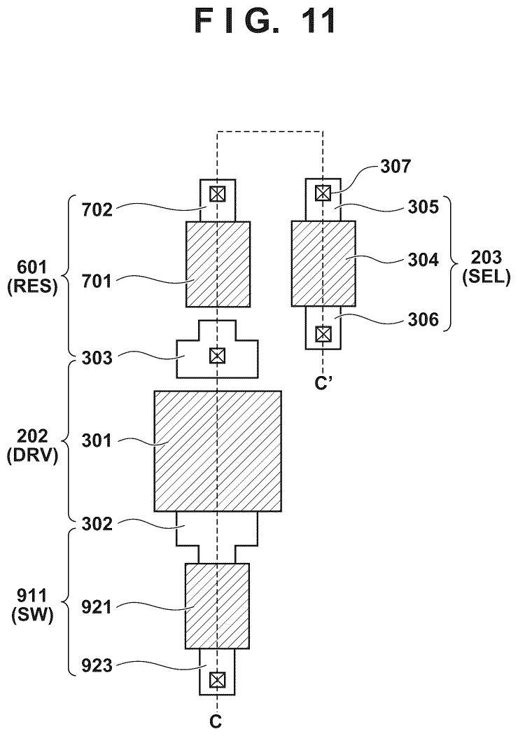

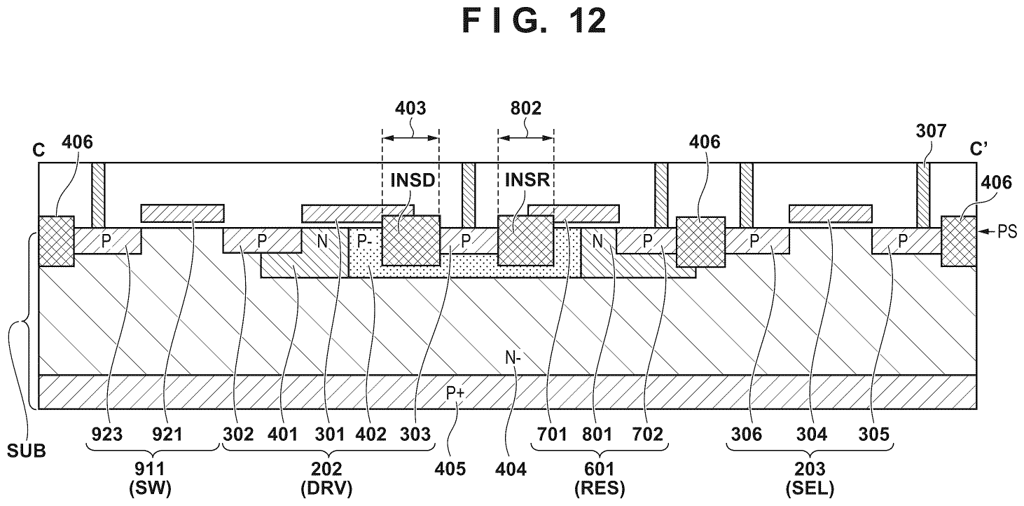

FIGS. 11 and 12 are a plan view and a sectional view, respectively, schematically showing the arrangement of the driving transistor 202, the write transistor 203, the reset transistor 601, and the light emission control transistor 911 of the pixel 102 shown in FIG. 10. FIG. 12 shows a section taken along a line C-C′ in FIG. 11. The light emission control transistor 911 can include a semiconductor region of the first conductivity type forming a source 923, a semiconductor region of the first conductivity type forming a drain 302, and a gate 921. In this example, the semiconductor region of the first conductivity type forming the drain 302 of the light emission control transistor 911 is in common with the semiconductor region of the first conductivity type forming the source 302 of the driving transistor 202. However, the semiconductor region of the first conductivity type forming the drain of the light emission control transistor 911 may be provided separately from the semiconductor region of the first conductivity type forming the source of the driving transistor 202.

Application examples of the above-described light-emitting device 101 will be described below. FIG. 13 is a schematic view showing an example of a display device 1000 according to an embodiment. The display device 1000 can include a touch panel 1003, a display panel 1005, a frame 1006, a circuit board 1007, and a battery 1008 between an upper cover 1001 and a lower cover 1009. The display panel 1005 is an application example of the light-emitting device 101. Flexible printed circuits (FPCs) 1002 and 1004 are respectively connected to the touch panel 1003 and the display panel 1005. Transistors are printed on the circuit board 1007. The battery 1008 is unnecessary if the display device is not portable equipment. Even when the display device is portable equipment, the battery 1008 may be provided at another position. The display device 1000 can include color filters of red, green, and blue. The color filters of red, green, and blue can be arranged in a delta array.

The display device 1000 can also be used for a display unit of a portable terminal. At this time, the display unit can have both a display function and an operation function. Examples of the portable terminal are a portable phone such as a smartphone, a tablet, and a head mounted display.

The display device 1000 can be used for a display unit of an image capturing device including an optical unit including a plurality of lenses, and an image sensor for receiving light having passed through the optical unit. The image capturing device can include a display unit for displaying information acquired by the image sensor. In addition, the display unit can be either a display unit exposed outside the image capturing device, or a display unit arranged in the finder. The image capturing device can be a digital camera or a digital video camera.

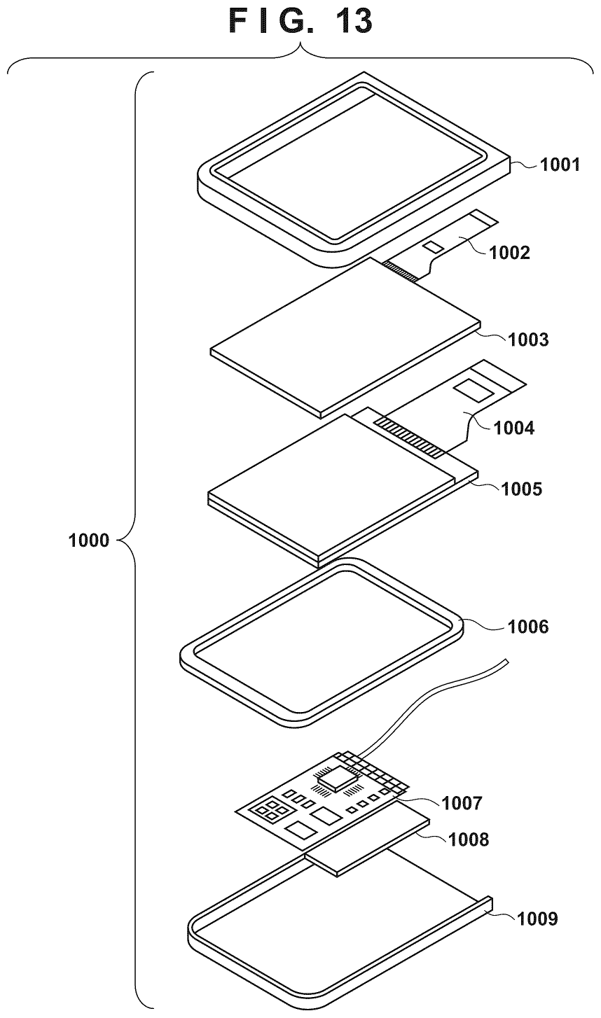

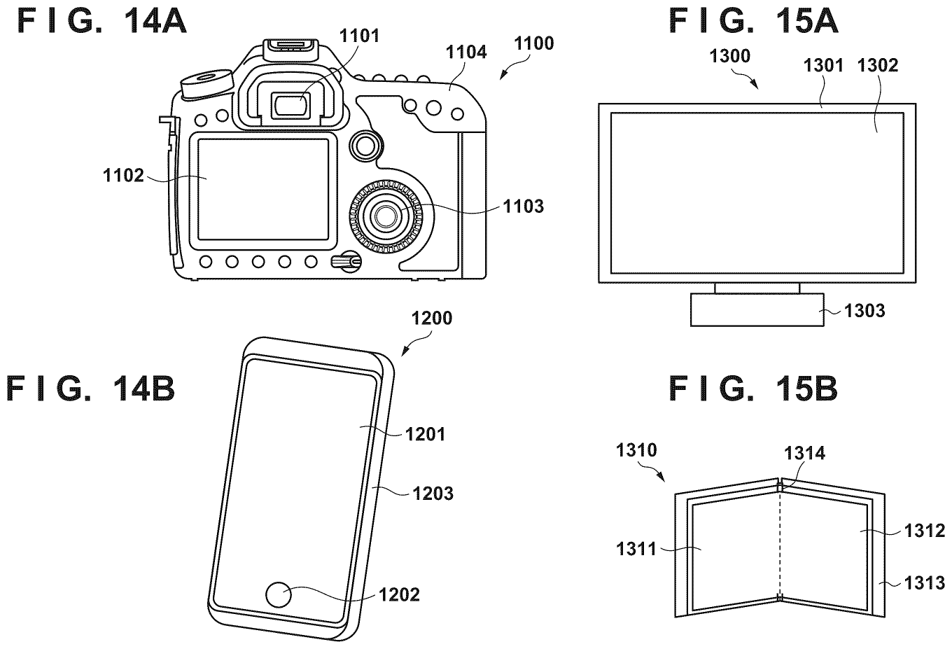

FIG. 14A is a schematic view showing an example of an image capturing device 1100 according to an embodiment. The image capturing device 1100 can include a viewfinder 1101, a rear display 1102, an operation unit 1103, and a housing 1104. The viewfinder 1101 may include the display device 1000. In this case, the display device 1000 can display not only an image to be captured but also environment information, image capturing instructions, and the like. Examples of the environment information are the intensity and direction of external light, the moving velocity of an object, and the possibility that an object is covered with an obstacle.

The image capturing device 1100 includes an optical unit (not shown). The optical unit includes a plurality of lenses, and forms an image on an image sensor that is accommodated in the housing 1104. The focal points of the plurality of lenses can be adjusted by adjusting the relative positions. This operation can also automatically be performed. The image capturing device may be called a photoelectric conversion device. Instead of sequentially capturing an image, the photoelectric conversion device can include, as an image capturing method, a method of detecting the difference from a previous image, a method of extracting an image from an always recorded image, or the like.

FIG. 14B is a schematic view showing an example of electronic equipment according to an embodiment. Electronic equipment 1200 includes a display unit 1201, an operation unit 1202, and a housing 1203. The housing 1203 can accommodate a circuit, a printed board including this circuit, a battery, and a communication unit. The operation unit 1202 may be a button or a touch-panel-type reaction unit. The operation unit may also be a biometric authentication unit that performs unlocking or the like by authenticating a fingerprint. The electronic equipment including the communication unit can also be regarded as communication equipment. The electronic equipment can further have a camera function by including a lens and an image sensor. An image captured by the camera function is displayed on the display unit. Examples of the electronic equipment are a smartphone and a laptop computer.

FIG. 15A is a schematic view showing one example of a display device 1300 according to an embodiment. The display device 1300 is applicable to a television monitor or a PC monitor. The display device 1300 includes a frame 1301 and a display unit 1302. The display unit 1302 is an application example of the light-emitting device 101.

The display device 1300 includes a base 1303 that supports the frame 1301 and the display unit 1302. The base 1303 is not limited to the form shown in FIG. 15A. The lower side of the frame 1301 may also function as the base. In addition, the frame 1301 and the display unit 1302 may be bent. The radius of curvature can be 5,000 mm (inclusive) to 6,000 mm (inclusive).

FIG. 15B is a schematic view showing another example of a display device 1310 according to an embodiment. The display device 1310 shown in FIG. 15B is configured to be foldable, that is, the display device 1310 is a so-called foldable display device. The display device 1310 includes a first display unit 1311, a second display unit 1312, a housing 1313, and a bending point 1314. Each of the first display unit 1311 and the second display unit 1312 is an application example of the light-emitting device 101. The first display unit 1311 and the second display unit 1312 may be one seamless display device. The first display unit 1311 and the second display unit 1312 can be divided by the bending point. The first display unit 1311 and the second display unit 1312 can display different images, and can also display one image together.

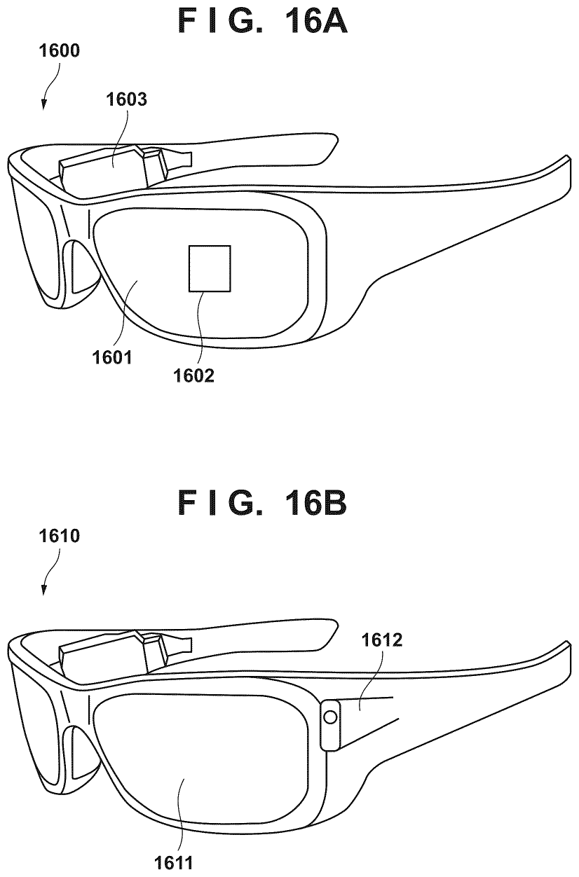

Application examples of the display device described above will be described with reference to FIGS. 16A and 16B. The display device can be applied to a system that can be worn as a wearable device such as smartglasses, an HMD, or a smart contact lens. An image capturing device used in such an application example includes an image capturing device capable of photoelectrically converting visible light and a display device capable of emitting visible light.

FIG. 16A shows the arrangement of glasses 1600 (smartglasses) according to one application example. An image capturing device 1602 such as a CMOS sensor or an SPAD is provided on the front surface side of a lens 1601 of the glasses 1600. In addition, the display device of each of the above-described embodiments is provided on the back surface side of the lens 1601.

The glasses 1600 further include a control device 1603. The control device 1603 functions as a power supply that supplies power to the image capturing device 1602 and the display device according to each embodiment. In addition, the control device 1603 controls the operations of the image capturing device 1602 and the display device. An optical system configured to condense light to the image capturing device 1602 is formed on the lens 1601.

FIG. 16B shows the arrangement of glasses 1610 (smartglasses) according to another application example. The glasses 1610 includes a control device 1612. An image capturing device corresponding to the image capturing device 1602 and a display device are mounted on the control device 1612. An optical system configured to project light emitted by the display device in the control device 1612 is formed in a lens 1611, and an image is projected to the lens 1611. The control device 1612 functions as a power supply that supplies power to the image capturing device and the display device, and controls the operations of the image capturing device and the display device. The control device may include a line-of-sight detection unit that detects the line of sight of a wearer. The detection of a line of sight may be done using infrared rays. An infrared ray emitting unit emits infrared rays to an eyeball of the user who is gazing at a displayed image. An image capturing unit including a light receiving element detects reflected light of the emitted infrared rays from the eyeball, thereby obtaining a captured image of the eyeball. A reduction unit for reducing light from the infrared ray emitting unit to the display unit in a planar view is provided, thereby reducing deterioration of image quality.

The line of sight of the user to the displayed image is detected from the captured image of the eyeball obtained by capturing the infrared rays. An arbitrary known method can be applied to the line-of-sight detection using the captured image of the eyeball. As an example, a line-of-sight detection method based on a Purkinje image obtained by reflection of irradiation light by a cornea can be used.

More specifically, line-of-sight detection processing based on pupil center corneal reflection is performed. Using pupil center corneal reflection, a line-of-sight vector representing the direction (rotation angle) of the eyeball is calculated based on the image of the pupil and the Purkinje image included in the captured image of the eyeball, thereby detecting the line-of-sight of the user.

The display device according to the embodiment of the present invention may include an image capturing device including a light receiving element, and a displayed image on the display device may be controlled based on the line-of-sight information of the user from the image capturing device.

More specifically, the display device decides a first display region at which the user is gazing and a second display region other than the first display region based on the line-of-sight information. The first display region and the second display region may be decided by the control device of the display device, or those decided by an external control device may be received. In the display region of the display device, the display resolution of the first display region may be controlled to be higher than the display resolution of the second display region. That is, the resolution of the second display region may be lower than that of the first display region.

In addition, the display region includes a first display region and a second display region different from the first display region, and a region of higher priority is decided from the first display region and the second display region based on line-of-sight information. The first display region and the second display region may be decided by the control device of the display device, or those decided by an external control device may be received. The resolution of the region of higher priority may be controlled to be higher than the resolution of the region other than the region of higher priority. That is, the resolution of the region of relatively low priority may be low.

Note that AI may be used to decide the first display region or the region of higher priority. The AI may be a model configured to estimate the angle of the line of sight and the distance to a target ahead the line of sight from the image of the eyeball using the image of the eyeball and the direction of actual viewing of the eyeball in the image as supervised data. The AI program may be held by the display device, the image capturing device, or an external device. If the external device holds the AI program, it is transmitted to the display device via communication.

When performing display control based on line-of-sight detection, smartglasses further including an image capturing device configured to capture the outside can preferably be applied. The smartglasses can display captured outside information in real time.

While the present invention has been described with reference to exemplary embodiments, it is to be understood that the invention is not limited to the disclosed exemplary embodiments. The scope of the following claims is to be accorded the broadest interpretation so as to encompass all such modifications and equivalent structures and functions.

This application claims the benefit of Japanese Patent Application No. 2023-198524, filed Nov. 22, 2023, which is hereby incorporated by reference herein in its entirety.

What is claimed is:

1. A light-emitting device including a plurality of pixels arranged in a substrate, wherein
each pixel includes a light-emitting element, a driving transistor configured to supply a current to the light-emitting element, and a write transistor configured to supply a signal voltage to a gate of the driving transistor, and
the driving transistor has an offset structure that includes an insulator between the gate and a semiconductor region forming one of a source and a drain of the driving transistor in an orthogonal projection to a main surface of the substrate.

2. The device according to claim 1, wherein
the gate is arranged on the main surface via a gate insulating film, and a depth of a bottom surface of the insulator using the main surface as a reference is greater than a depth of a bottom surface of the semiconductor region using the main surface as a reference.

3. The device according to claim 2, wherein
the insulator includes a Shallow Trench Isolation (STI).

4. The device according to claim 1, wherein
the offset structure is a drain offset structure that includes the insulator between the drain and the gate in the orthogonal projection to the main surface of the substrate.

5. The device according to claim 1, wherein
the source is a first semiconductor region of a first conductivity type, the drain is a second semiconductor region of the first conductivity type,
in a current path from the first semiconductor region to the second semiconductor region, a third semiconductor region of a second conductivity type and a fourth semiconductor region of the first conductivity type are arranged in this order, and
a net impurity concentration of the first conductivity type in the fourth semiconductor region is lower than a net impurity concentration of the first conductivity type in the second semiconductor region.

6. The device according to claim 1, wherein
the offset structure is a drain offset structure that includes the insulator between the drain and the gate in the orthogonal projection to the main surface of the substrate,
each pixel further includes a reset transistor configured to reset the light-emitting element, and
the reset transistor has a source offset structure that includes an insulator between a source of the reset transistor and a gate of the reset transistor in the orthogonal projection.

7. The device according to claim 6, wherein
the source of the reset transistor is in common with the drain of the driving transistor.

8. The device according to claim 6, wherein
a depth of a bottom surface of the insulator in the source offset structure using the main surface as a reference is greater than a depth of a bottom surface of the source of the reset transistor using the main surface as a reference.

9. The device according to claim 8, wherein
the insulator in the source offset structure includes a Shallow Trench Isolation (STI).

10. The device according to claim 6, wherein
the source of the driving transistor is a first semiconductor region of a first conductivity type, and the drain of the driving transistor is a second semiconductor region of the first conductivity type,
the drain of the reset transistor is a fifth semiconductor region of the first conductivity type,
in a current path from the first semiconductor region to the second semiconductor region, a third semiconductor region of a second conductivity type and a fourth semiconductor region of the first conductivity type are arranged in this order,
a net impurity concentration of the first conductivity type in the fourth semiconductor region is lower than a net impurity concentration of the first conductivity type in the second semiconductor region, and
in a current path from the second semiconductor region to the fifth semiconductor region, the fourth semiconductor region of the first conductivity type and a sixth semiconductor region of the second conductivity type are arranged in this order.

11. The device according to claim 6, wherein
a length of the insulator of the driving transistor in a channel length direction of the driving transistor is different from a length of the insulator of the reset transistor in a channel length direction of the reset transistor.

12. The device according to claim 1, wherein
each pixel further includes a light emission control transistor configured to control a period during which the light-emitting element is caused to emit light.

13. The device according to claim 1, wherein
the plurality of pixels are arranged to form a plurality of rows and a plurality of columns.

14. A display device comprising a light-emitting device defined in claim 1.

15. A photoelectric conversion device comprising an optical unit including a plurality of lenses, an image sensor configured to receive light having passed through the optical unit, and a display unit configured to display an image,
wherein the display unit includes a light-emitting device defined in claim 1.

16. Electronic equipment comprising a housing provided with a display unit, and a communication unit provided in the housing and configured to perform external communication,
wherein the display unit includes a light-emitting device defined in claim 1.

17. A wearable device comprising a display device configured to display an image,
wherein the display device includes a light-emitting device defined in claim 1.
